(19) United States
(12) Patent Application Publication
(10) Pub. No.: US 2005/0210349 A1
(43) Pub. Date: Sep. 22, 2005

(54) Scan test tools, models and/or methods

(76) Inventors: Michael R. Lambert, Fort Collins, CO (US); John G. Rohrbaugh, Fort Collins, CO (US)

Correspondence Address: AGILENT TECHNOLOGIES, INC.;Legal Department, DL429, Intellectual Property Administration, P.O. Box 7599, Loveland, CO, 80537-0599, US

(21) Appl. No.: 10/806,485

(22) Filed: Mar. 22, 2004

(51) Int. Cl. G01R 31/28

(52) U.S. Cl. 714/726

(57) ABSTRACT

Tools, systems and/or methods for use in a test process of a circuit device. Such tools, systems and/or methods may provide for identifying respective parent and branch portions of a scan chain of a circuit device, the scan chain having at least one scan input and one or more scan outputs and a plurality of scan cells; and creating a model of the scan chain, including creating a dummy cell chain which includes a branch portion of the scan chain and has one or more dummy cells disposed therein connected between the branch portion and the scan input.

### BACKGROUND

As integrated circuit (IC) devices become more and more intricate and sophisticated, as, for example, when they continue to have larger and larger numbers of interrelated parts or elements added thereto, and/or when IC devices are connected to printed circuit (PC) boards in increasingly more elaborate fashions, with higher numbers of interrelated elements, they can and often do present testing difficulties. In many such cases, it can be difficult to devise a test pattern that generates the desired response to be captured. This is true not only for system and functional testing but is also true for “in-circuit,” “structural” or “scan” testing, where the increasing numbers of scan flops in/on the scan path(s) presented by any particular IC device and/or circuit board generate not only expanded testing opportunities, but also provide for a potentially staggering, possibly overwhelming volume of scan test data due to increases in the numbers of scan cells or flops disposed on/in the IC.

In particular, the numbers of scan flops in scan chains or paths presented by IC devices and/or boards has increased from what were at one time relatively low numbers of scan flops in substantially single serial paths to many more scan flops in much larger serial paths, in multiple parallel scan chains, or both. A scan chain is generally a number of scan flops stitched or connected together forming a chain or path, each path generally having one scan input (SIN) and one scan output (SOUT). As the number scan flops in an IC increases, the IC may have more flops per chain and/or multiple chains, each chain having a corresponding scan input (SIN) and a corresponding scan output (SOUT). One result may be that the IC then has what may be a relatively large number of multiple inputs and outputs. However, in many of these cases, the volume of scan test data is usually multiplied to very large levels. A development called “Illinois scan,” which involves having several scan chains share a common scan input, can provide some assistance in reducing scan data volume.

During the actual test process, respective test vectors are scanned into respective scan chains, and one bit at a time from each respective test vector is presented at each respective SIN. This bit is then passed from the first scan flop to the next scan flop in the chain and continues until all bits of the test vector are inputted. This is referred to as scanning in a test vector. As a test vector is scanned in, each successive scan flop of the scan chain receives the respective bits in the same serial fashion as originally presented. Thus, such integrated circuit scan chains then pass these bits or consequent response bits through the scan chain to the SOUT which then communicates these data to the test equipment data analyzer for determination of the passage or failure of the test.

The issue of increasing scan test data volume by addition of larger and larger numbers of scan flops and/or the multiplication of scan chains in/on an IC provides benefits in increased testing capability, i.e., in providing for increased test coverage. However, due to the larger amounts of data traveling to and from the IC, through the larger numbers of scan flops, the test execution times will also undesirably increase and the data may consume increasing amounts of tester memory. In addition, planning for and using and interpreting the increased data volume, input and/or output, can be difficult, and increasing the numbers of SINs and/or SOUTs may result in undesirably increased external connect points and/or increased real estate or size of the IC. Moreover, although some conventional testing equipment and tools for automated test pattern generation have been adapted to support shared scan chain inputs as in the “Illinois scan,” such equipment and tools have generally not currently been flexible enough to support some other methods of addressing increasing scan data volume problems.

### SUMMARY

Disclosed are tools, systems and/or methods for use in a test process of a circuit device. Such tools, systems and/or methods may provide for identifying respective parent and branch portions of a scan chain of a circuit device, the scan chain having at least one scan input and one or more scan outputs and a plurality of scan cells; and creating a model of the scan chain, including creating a dummy cell chain which includes a branch portion of the scan chain connected with one or more dummy cells and the scan input.

### BRIEF DESCRIPTION OF THE DRAWINGS

Illustrative embodiments of the invention are depicted in the drawings, in which:

FIG. 1A illustrates an integrated circuit incorporating a scan chain;

FIG. 1B illustrates an alternative integrated circuit incorporating a scan chain;

FIG. 2A illustrates a schematic representation of a scan chain like that in the integrated circuit of FIG. 1A;

FIG. 2B illustrates a schematic representation of a scan chain like that in the alternative integrated circuit of FIG. 1B;

FIG. 3A illustrates an alternative integrated circuit incorporating a branched or branch scan chain;

FIG. 3B illustrates a further alternative integrated circuit also incorporating a branched or branch scan chain;

FIG. 4 illustrates a schematic representation of a scan chain with a branched or branch chain like that in the integrated circuits of FIGS. 3A and/or 3B;

FIG. 5 illustrates an alternative schematic representation of a scan chain with a branched or branch chain presenting a scan cell ordering like that presented by the integrated circuits in FIGS. 3A and/or 3B and the schematic representation in FIG. 4;

FIG. 6 is a schematic representation of a scan chain with a branched or branch chain like that in the schematic representation of FIG. 4;

FIG. 7 is an alternative schematic representation of a scan chain with a branched or branch chain like that in the schematic representation in FIG. 5;

FIG. 8 shows a still further alternative integrated circuit not unlike those in FIGS. 3A and/or 3B, here incorporating a plurality of branched or branch scan chains;

FIG. 9 is a schematic representation of a scan chain with a plurality of branched or branch chains like that in the integrated circuit of FIG. 8;

FIG. 10 is an alternative schematic representation of a scan chain with a plurality of branched or branch chains presenting a scan cell ordering like that presented by the integrated circuit of FIG. 8 and the schematic representation in FIG. 9;

FIG. 11 which includes sub-FIGS. 11A and 11B, at least partially illustrates alternative methods in those sub-FIGS. 11A and 11B for setting up tests for IC devices and/or circuit boards; and,

FIG. 12 which includes sub-FIGS. 12A and 12B, represents alternative methods for testing IC devices and/or circuit boards.

### DETAILED DESCRIPTION

There are several common forms of test that are used to verify IC devices and/or circuit boards; including for example, parametric test, functional test and structural test. Whereas functional tests verify that an IC device or circuit board operates as designed, structural tests verify that the components of an IC device or circuit board are correctly connected and operational. Often called “scan” testing, structural testing enables the testing of structures which are deeply embedded within an integrated circuit (IC) device. Rather than testing the IC device's internal structure by applying stimulus to the IC device's inputs (as would be done in “functional” testing), structural or scan testing involves shifting a series of test vectors into the core of an IC device, and after each test vector is shifted in, launching the test vector and capturing a response. Each response is then shifted out of the IC device. In this manner, a tester can verify that many, if not all of a particular IC device's elements are present and operational. An assumption of structural or scan testing is that if all elements are present and operational, then the elements will contribute to performing the greater and intended functions of the IC device (e.g., adding, shifting, etc.), and the IC will function as designed. Note, though at some points referred to as testing of an IC device, such structural testing can be expanded to the board level, as well. When designing a board, a designer can link signals of each IC device and/or other functional circuit elements at the board level (e.g., mode, shift and data I/O signals) to thereby expand structural testing to the board test level. Thus, all references to an IC or IC device thus also include and are intended to encompass functional circuits or circuit elements in, on or as parts of IC devices and/or circuit boards, as well as including the boards themselves.

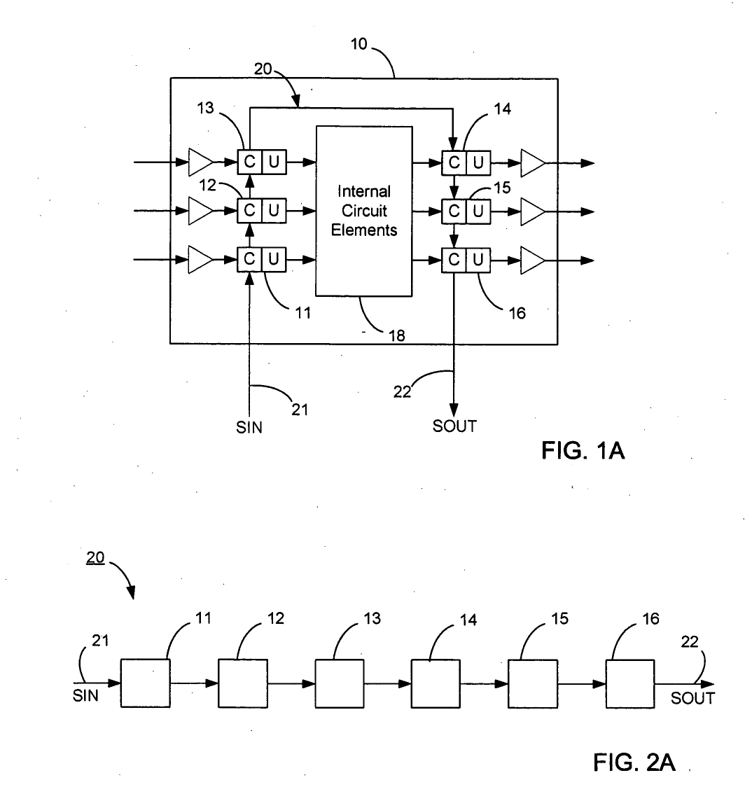

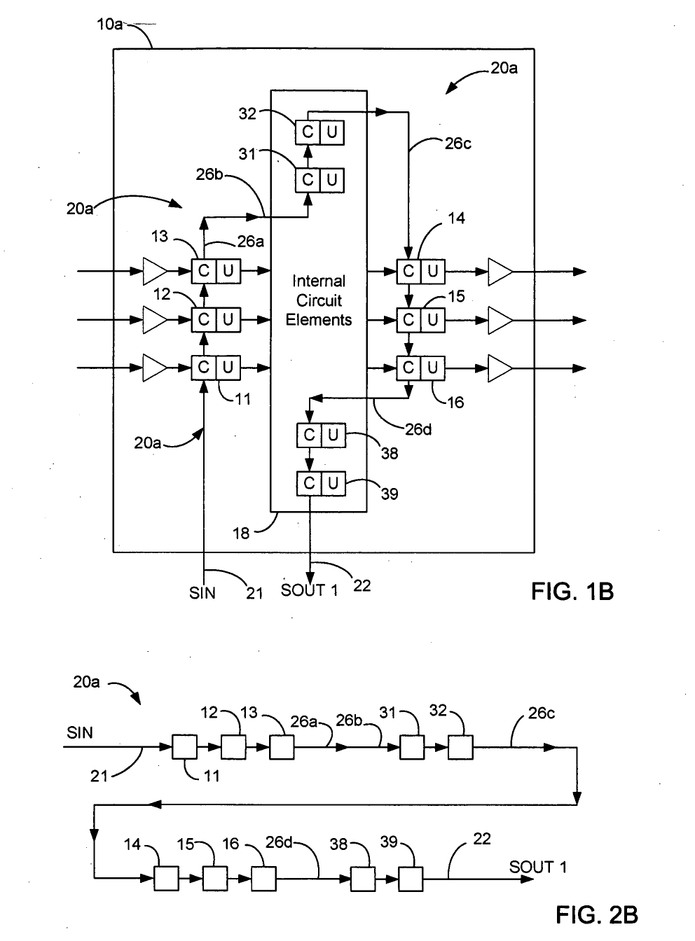

FIG. 1A illustrates a conventional IC device 10 incorporating but one example of a scan chain 20 including multiple elements or cells 11-16, here shown for the purpose of structural testing. See also FIG. 2A for a schematic view of a scan chain 20 like that depicted in the IC device 10 of FIG. 1A. It should first be noted that the descriptions herein are applicable to generalized scan testing; i.e., scan testing of any sort. Further however, the embodiment shown in FIG. 1A may be indicative of a boundary-type of scan chain configuration, which is but one of many forms of scan testing useful herewith. In the example of FIG. 1A, all of the scan cells 11-16 are shown wrapped around the internal circuit elements 18 and are disposed between the respective IC inputs/outputs and the internal circuit elements 18. Contrarily however, as shown in FIG. 1B, a further example of what may be a more generalized scan chain situation appears where what may be many if not all of the scan flops in the IC may be made scannable. This may then also include any boundary scan flops and/or any flops disposed in the internal circuitry 18 (see flops or scan cells 31, 32 and 38, 39, in FIG. 1B, e.g.). In some desired embodiments, it may be that complete, or 100 percent scan testing may be possible wherein the entire state of the IC can be specified via scanning in values. A schematic view of a scan chain 20a which may result from a configuration as in FIG. 1B, is shown in FIG. 2B. Note, the examples of FIGS. 1A, 1B, 2A and 2B are serial scan chains with one scan input 21 (SIN) and one scan output 22 (SOUT).

An IC device 10 which is designed for structural or like testing is commonly referred to as being “designed for test” (DFT), and therefore incorporates “design for test” (DFT) structures 11-16 as in FIGS. 1A and 1B, and structures 31, 32 and/or 38, 39 as in FIG. 1B. Structures 11-16 and/or structures 31, 32 and/or 38, 39 may be referred to hereafter often as scan cells 11-16, 31, 32 and/or 38, 39, though they may have other forms and/or designations. In one form, these cells 11-16, 31, 32 and/or 38, 39 are flip-flops, or commonly, flops 11-16, 31, 32 and/or 38, 39; although they may have or be more multifaceted or multipurpose circuit elements and/or functionalities. As shown in FIGS. 1A and 1B, there are scan cells wrapped around the internal circuit elements 18; namely three exemplary scan cells 11, 12, 13 on input sides of the internal circuit elements 18 of device 10, and three exemplary scan cells 14, 15, 16 on corresponding output sides of the elements 18. Note, elements 18 may represent a core or cores or other sorts of circuit elements. A scan input (SIN) 21 and a scan output (SOUT) 22 are also shown. A scan chain 20 as in the FIG. 1A embodiment is thus provided which proceeds from the SIN 21 serially through the input side scan cells 11, 12, 13, then through the output side cells 14, 15, 16 to the SOUT 22. A schematic representation of this scan chain 20 is also shown in FIG. 2A, though not including the internal circuit elements or other topographical features and/or connections of device 10. A scan chain may be any given number of scan flops stitched or connected together forming a chain with any number, though usually a limited number of inputs, e.g., one input (SIN) and in these embodiments, one corresponding output (SOUT). Note, as introduced above, the exemplary embodiment of FIG. 1B may be indicative of including not only boundary-type scan cells 11-16, but also some scan flops resident in the internal circuitry of the device 10a. This may create a scan chain 20a as shown in FIG. 2B which proceeds from the scan input (SIN) 21 through some boundary scan cells 11, 12, 13 then through internal scan cells 31, 32 out through boundary cells 14, 15, 16 and here finally through internal scan cells 38, 39 to and through scan output (SOUT) 22. Some of the interconnections 26a, 26b, 26c and 26d between some of the boundary and internal scan cells are also shown in FIGS. 1B and 2B (note, where there is no branching, e.g., as shown in FIGS. 1B and 2B, the interconnections 26a, 26b may be effectively represented as an unbroken continuous connection).

Thus, generalized scan testing of any type is accommodated hereby; including, but in no event limited to boundary testing. For example, the generalized forms of scan testing available for use with/in other embodiments according hereto may include, as shown in FIG. 1B, the additional flip-flops or scan cells 31, 32 and/or 38, 39 which are shown connected in a scan chain 20a for the alternative IC device 10a thereof. Such scan flops 31, 32 and/or 38, 39 may be connected in other chains not including the boundary scan elements 11-16. In such examples, the scan chain 20a may remain a single serial chain, but may generally include scan cells or flops existing inside the internal circuit elements 18. Thus, it may be in one or more alternative embodiments that no boundary scan elements are included in the respective chain(s), or simply a selected one or a few such elements may be included. Thus, the scan chain may be comprised wholly of scan cells from the internal circuit elements, or additionally, partially or wholly comprised of boundary scan cells. From a slightly different view; the methods and/or tools hereof may be targeted to any internal scan alone and/or may be operable with or without boundary scan elements or strategies. It may be noted here that there is the commonly understood form of boundary scan, which is often considered closely tied to the IEEE 1149.1 standard, and there is a similar form of scanning which is like boundary scan, where the perimeter of one or more cores or other internal circuit element(s) is “wrapped” with one or more scan cells, and both of these among any other scan form are intended to be usable in and/or with the systems, tools and/or methods hereof. More particularly, it is understood that the commonly understood type of boundary scan is the IEEE 1149.1 standard which strictly provides only for scan flops at the inputs and/or outputs (I/Os) of the IC device, and thus cannot include any scan flops from inside the circuit. The second form of scan which is like boundary scan involves the general idea of wrapping scannable flops around a portion of circuitry without necessarily having such flops at the I/Os of the IC device. FIG. 1A may be interpreted as depicting either or both of these types of scan.

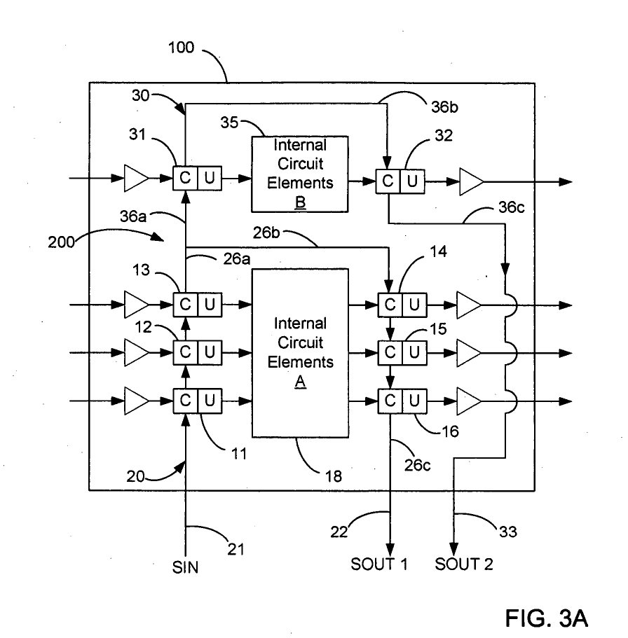

A further alternative IC device 100 is shown in FIG. 3A and includes internal circuit elements or a core or cores 18 as in the IC embodiments of FIGS. 1A and 1B (hereafter collectively and/or alternatively referred to as internal circuit elements A 18). Alternative device 100 may also include scan cells 11-16 as before, and thus, a base or parent scan chain 20 with a scan input 21 and a scan output, here referred to as scan output1, or SOUT1 22, are also included as before. However, here, an additional branch or stub scan chain 30 with scan cells 31 and 32 and a secondary scan output, here SOUT2 33 may also be included in this alternative IC device 100. Branch or stub chain 30 is connected to and branches off of the base or parent scan chain 20 and thereby provides an overall scan chain 200 with parallel parts which will be described further below. The branching shown and described herein is the intended meaning of either branch or stub or other similar alternative descriptors, such as fork, or forked or Y-shaped, or the like.

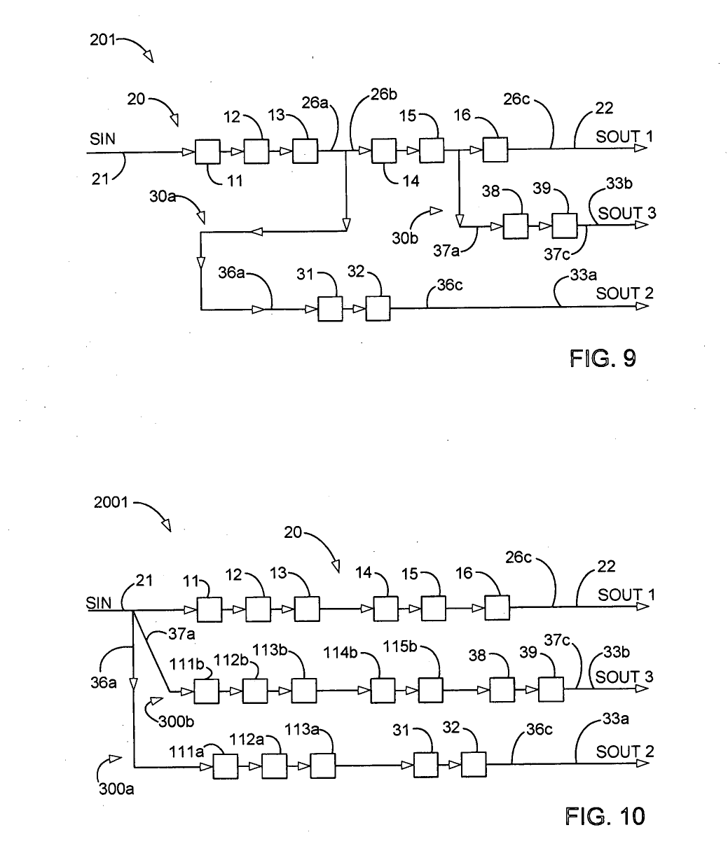

Branch or stub chain 30 may be disposed as shown in this alternative as operative relative to a secondary set of internal circuit elements, e.g., a second core or cores or other elements, hereafter collectively and/or discretely referred to as internal circuit elements B 35. Scan cells 31 and 32 here may thus represent respective input and output cells like those corresponding input and output cells 11-13 and 14-16 described above. Scan cells 31 and/or 32 or the like may alternatively represent other types of scan cells or test cells as such may be useful in a scan or like chain as described herein. Note, as above, although this first branched chain exemplary embodiment may be considered as being implemented for a boundary-type scan, this is shown merely for simplicity of description first, as other scan cells may be used together with or instead of boundary scan cells as shown in the exemplary embodiment of FIG. 3B (and FIG. 8 et al. as described further below). More particularly, FIG. 3B presents an alternative IC device 100a having a branched scan chain wherein the scan flops 31 and 32 here represent internal scan elements as opposed to what may be considered boundary scan elements shown in FIG. 3A.

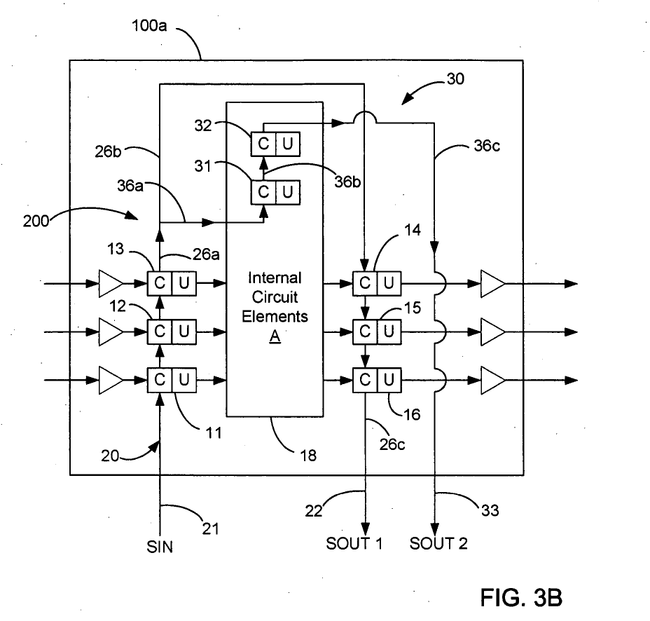

From either or both of the FIGS. 3A and/or 3B embodiments, the overall scan chain 200, which includes the base chain 20 and the branch chain 30 therefrom, is also shown in FIG. 4, though schematically not including the internal circuit elements A 18 or B 35 (although the scan cell elements form the internal circuit elements 35 are shown) or other topographical elements or connections for simplicity in depiction. The branching is shown in both FIGS. 3A, 3B and FIG. 4, particularly as depicted by the base chain connection portions 26a, 26b, and 26c, which are shown relative to the branch or stub portion 36a which is emanating from the point of connection between portions 26a and 26b. The remainder branch or stub portions 36b and 36c of the branch or stub leading to the SOUT2 33 are also indicated for completion of the branch or stub chain 30 exemplified here. Connection portions 26a, 26b, 26c and 36a, 36b, 36c are depicted schematically, but may be electrical conductors or the like which provide communication of signals from one cell to another. Note, the base chain 20 is, as it was in the embodiments of FIGS. 1A, 1B, 2A and 2B, from SIN 21 to SOUT1 22 and includes the scan cells 11, 12, 13, and 14, 15, 16. Note further that although the chain including cells 11, 12, 13, and 14, 15, 16 and connections portions 26a, 26b, 26c is here denominated as the base chain, it is done so for simplicity in the purposes of the description only, and not for limitation. I.e., the base chain could instead be thought of as the chain including cells 11, 12, 13, and 31, 32 and connections 36a, 36b and 36c, with the branch or stub instead including the cells 14, 15, 16 and connections 26b and 26c.

Branched scan chains like those exemplarily shown in FIGS. 3A and/or 3B may generally be a part of a newer concept of parallel scanning which may in some instances be referred to as massive or massively parallel scan which is also known as an extension of scan folding. These are some newer configurations of scan chains which may be used to assist with or mitigate the problem(s) of increased scan data volume(s). The general idea is that having a branched scan chain is helpful in implementing some forms of scan chain parallelization. Such parallel scan chains are generally a given number of scan flops stitched or connected together forming a chain or path, including one or more branched or stub scan chains or paths such that the overall chains have one or more scan inputs (SINs) and one or more scan outputs (SOUTs). The result may then be an IC having what may be a relatively large number of multiple inputs and/or outputs which are branched off or are stubs emanating from what might otherwise generally have been a serial chain. It may be noted that for the purposes of convention in this disclosure, multiple scan outputs (SOUTs) will be shown and described, however, in usual scan folding and/or massive parallel scanning, other creative methods are often used to compress the multiple scan outputs (SOUTs) into a single output because it is not desirable to increase the actual number of physical scan inputs or outputs. Then, during the actual test process, respective test vectors are scanned into respective scan chains, and one bit at a time from each respective test vector is presented at each respective SIN. When a branch or stub from the serial chain is reached these bits fan out to also populate the branch or stub. Such integrated circuit scan chains with these branched scan paths are generally designed so that the flops within the branch or stub should thus receive the same bits as the parent segment or the output response will represent incorrect results, thereby invalidating the test. In many examples, this parallel scan method puts many small scan chains in parallel with a common SIN, drastically reducing test time (more scans running in parallel reduces test time). Moreover, such parallelism can be achieved without drastically increasing the number of scan chain inputs, thus reducing the number of IC inputs. In creating the parallel scan chains, it is common to have a number of scan flops that do not divide evenly by the targeted scan chain length, thereby producing a remainder that can then be added to an existing one of the small parallel chains as a branch or stub. Because of the very novelty of these techniques of stitching branched or stubbed scan chains, the problem of generating appropriate tests, test methods/processes and/or test vectors, or how to sufficiently feed such vectors into these branched chains had not previously been faced, particularly in an automated test generation environment. Note, however, branched scan chains may have additional applications above and beyond scan chain parallelization. Perhaps there may have been an error in hooking up a scan chain and a branch was introduced by mistake. Then, perhaps the tools and/or methods hereof would handle this configuration rather than requiring a redesign of the IC.

However, though it may be straightforward to build an IC device like device 100 or 100a in FIGS. 3A and/or 3B having one or more branched chains like chain 200 in FIG. 4, it may be that certain types of test equipment or test tools and/or software may not be adapted to readily appreciate branched chains, how to prepare tests therefor and/or how to apply the ultimate tests thereof. More particularly, conventional automated test pattern generation (ATPG) is not currently flexible enough to support branched scan chains as the conventional algorithms thereof are not only based on single inputs and single outputs; these indeed are designed to flag a branched chain as a design error. In conventional ATPG, the netlist representation of the scan chain (i.e., netlist connectivity information which includes scan chain connectivity information) does not expect branching scan chains (except at the initial scan input which allows the classic “Illinois scan”), and when the ATPG reaches a branch in a scan chain, it thus determines it to be an error. In particular, up until this point, it was much more likely that the branch was a design connectivity error rather than a feature. Also, it is more difficult for tool writers to handle a structure that deviates from the classic one input/one output scan chain. It may have been a relatively simple task to map “Illinois scan” to a group of one input/one output scan chains. In such a case, the only thing to track is that the data going into all of the scan inputs must be identical (because they are really the same input). However, it is less obvious how a tool writer might map arbitrary branches in scan chains back to the one input/one output scan chain model, which is the point of the tools, systems and/or methods described herein.

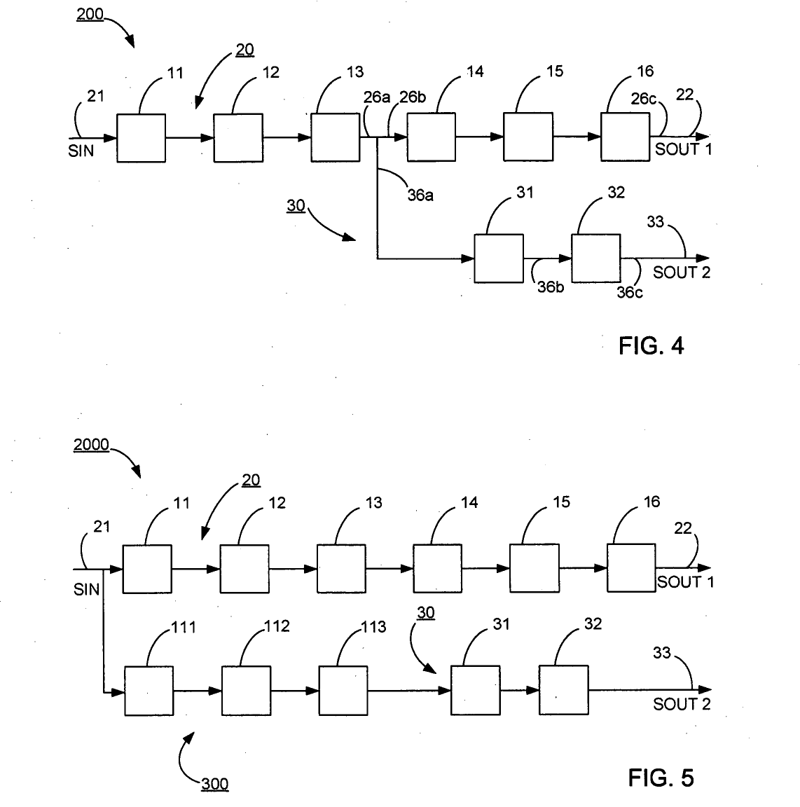

In FIG. 5, an alternative form 2000 of the scan chain 200 of FIG. 4 is shown in which some additional cells 111, 112, 113 in an additional portion of an overall branch chain 300 are depicted. Note, the branch chain 30 of the FIG. 4 embodiment is now connected to the additional cells 111, 112, 113, here also known or referred to as dummy cells 111, 112, 113 of the new branch chain 300. Such a scan chain 2000 may be a replica, equivalent or model of the branched chain 200 of FIG. 4 inasmuch as they may operate in similar fashions and/or provide similar results. However, this would solve the issue of the ATPG scan tracing or other test software not being able to recognize the validity of branched chains.

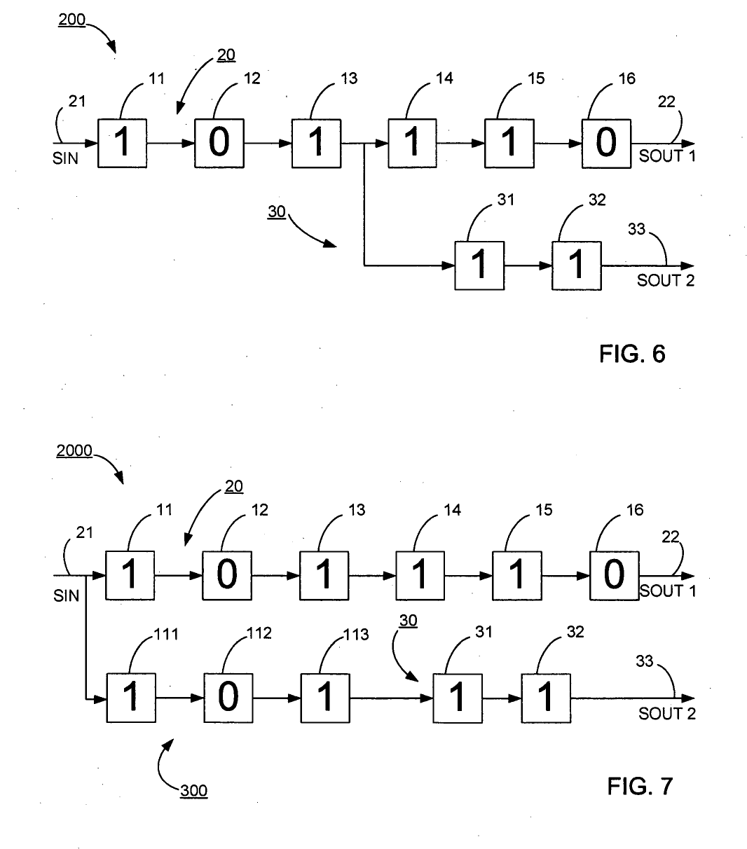

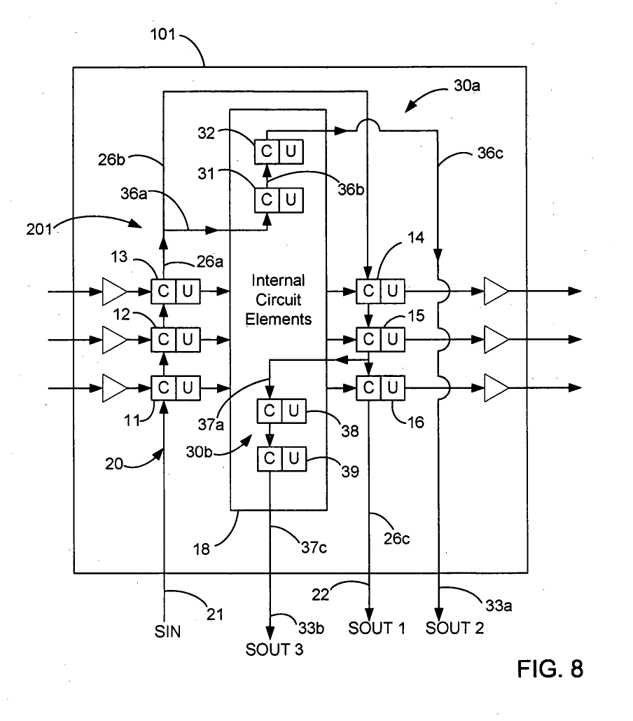

In a more particular example as shown in FIGS. 6 and 7, a test vector is shown being scanned into both of the embodiments of FIGS. 4 and 5 respectively. First note that when a test vector is scanned into a chain, one bit at a time is presented at the SIN 21. Such bits are represented in FIGS. 6 and 7 as respective ones (1's) and zeros 0's; see the one (1) in cell 11 and the zero (0) in cell 12. The first bit is passed from the first scan cell or flop 11 to the next scan cell or flop 12 in the chain with each pulse of the shift clock or test clock and continues in this serial fashion until all bits of the test vector have been inputted. This is referred to as scanning in a test vector. As a test vector is scanned in, each segment or cell of the chain receives the same bits. When a stub or branch is reached these bits fan out to also populate the stub; see FIG. 6, e.g., when a bit is passed from cell 13 to and through the branching connection, that bit populates both the base cell 14 and the branch cell 31 at substantially the same time. Then, that bit/those bits are simultaneously passed to the next cells, cells 15 and 32, respectively. Thus, whatever bit is in cell 14, e.g., is similarly in cell 31, and likewise whatever bit is populating cell 15 is simultaneously populating cell 32. With conventional test pattern generation tools, it may be most common that the corresponding cells within the branch or stub receive the same bits as the parent or base segment or portion of the scan chain or the vector generation tool (or automated test pattern generator, ATPG) will produce incorrect results, invalidating the test vector. As described above, industry standard atpg (auto test pattern generation) tools do not allow a scan chain to have a stub within a scan chain.

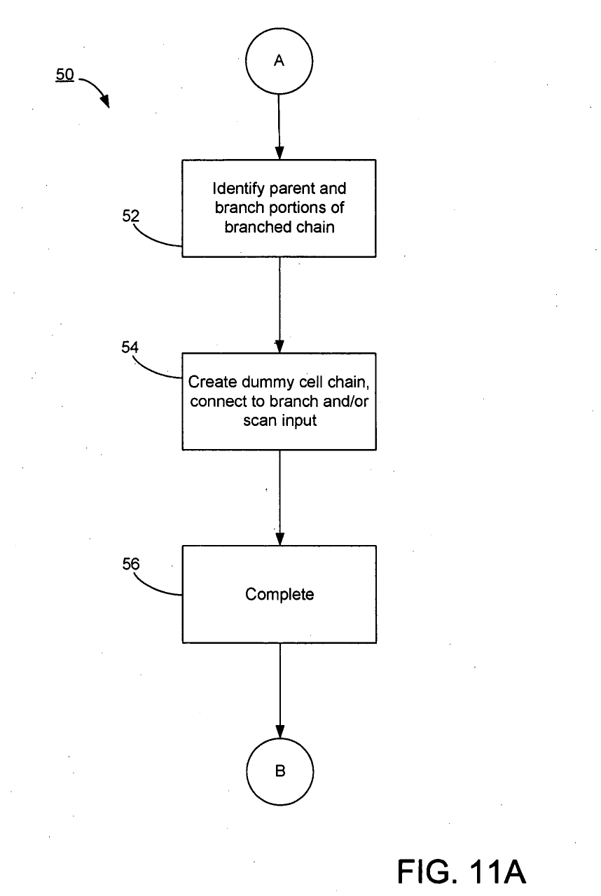

However, it has been found that a way to ensure that the bits in the stub 30 are correct, dummy cells or flops may be added to the model as shown by the schematics of FIGS. 5 and 7. Note this may also be done for the actual IC devices (but the addition of actual flops in this manner to the actual IC device would result in the “Illinois scan” technique), or more usually for an electronic representation or model thereof representing what the automated test pattern generator (ATPG) sees when it presents a test sequence or flow thereto. The dummy flops are added in the model to form a new chain, so that the ATPG tool will generate a test which loads the correct bits of the test vector into the stubbed cells or flops. The number of dummy cells or flops added is the same number of cells or flops in the base chain 20 from SIN 21 to the stubbed or branched point of departure (see e.g., the point between connections 26a and 26b in FIGS. 3 and 4, for example, though other branch points may also occur, see description of FIGS. 8 and 9, e.g., below) from the parent or base chain.

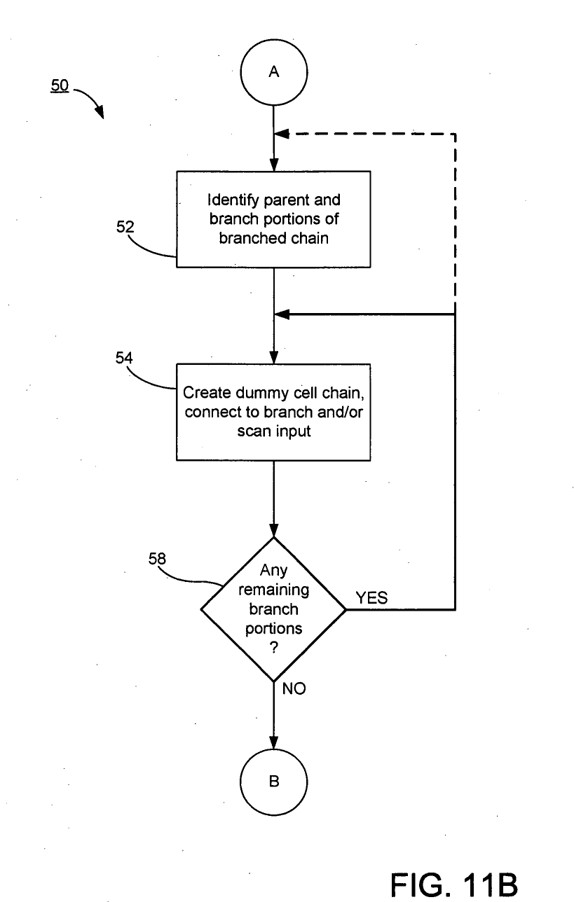

A further more diverse example is shown in FIGS. 8, 9 and 10, wherein a more highly varied IC device 101 is shown which has two branches (thus, representing a plurality, two or more, branches) off a parent or base chain 20. The branches are designated 30a and 30b and together with the base chain 20, combine to create an overall chain 201 having one input, SIN 21 and three outputs, SOUT1 22, SOUT2 33a, and SOUT3 33b. The first branch 30a is substantially the same as that shown and described for the FIG. 3B embodiment and indeed the same reference designations are used here as well. The second branch 30b includes internal flops 38, 39 not unlike those introduced in FIG. 1B; however, the branch designations 37a and 37c are used to show the branch from the base chain 20 as it occurs between the scan cells 15 and 16 thereof. The branched chain 201 is shown schematically in FIG. 9 apart from the other non-scan elements of FIG. 8. A model 2001 according to the teachings hereof is shown in FIG. 10 which includes the base chain 20 (with its scan elements 11, 12, 13, 14, 15 and 16) and two model branches 300a and 300b. The model branches 300a and 300b include the respective branch scan cells; cells 31, 32 and 38, 39, and additional, dummy cells. In particular though, it should be noted that the number of dummy cells in each branch corresponds directly to the number of parent cells occurring prior to the branch in the FIGS. 8 and 9 representations of the overall scan chain 201. Thus, the first dummy branch 300a has three dummy scan cells 111a, 112a, and 113a disposed in the dummy branch chain prior to the scan cells 31, 32, and the second dummy branch 300b has five dummy cells 111b, 112b, 113b, 114b and 115b disposed in that dummy chain prior to its respective scan cells 38, 39. Note also that although the chain including cells 11, 12, 13, and 14, 15, 16 and connections portions 26a, 26b, 26c is here denominated as the base chain 20, it is done so for simplicity in the purposes of the description only, and not for limitation. I.e., the base chain 20 could instead be thought of as the chain including cells 11, 12, 13, and 31, 32 and connections 36a, 36b and 36c, with the branch or stub instead including the cells 14, 15, 16 and connections 26b and 26c (or the alternative with cells 11, 12, 13, and 14, 15, 38 and 39 and connections portions 26a, 26b, 37a and 37c). Note moreover that if a scan chain has multiple branches such as this, the present methods and tools may be applied recursively to every one. Thus, not only can these cover a base chain with one or more branches, it is also possible to have a “branch of a branch” within a scan chain. See for example, where as a scan chain the base chain 20 is thought of as the chain including cells 11, 12, 13, and 31, 32 and connections 36a, 36b and 36c, with the branch or stub instead including the cells 14, 15, 16 and connections 26b and 26c (e.g., a generic parent P and a generic branch P1 occuring after N flops on P). Then, the branch (generic P1) including the cells 14, 15, 16 and connections 26b and 26c further has a branch (generic P11) including cells 38 and 39 occuring between flops 15 and 16 here (or more generically after M flops on P1). In this case, the first branch (P1) is acting as a parent or base chain relative to the second branch (P11), just like the base chain 20 (P) is a parent to the first branch (P1).

There may be additional considerations as to the differences between branches and/or the parent chain. For example, one branch could be inverted from another due to an inverter being used to buffer one branch but not the other. Given that this complicates the design, this would more likely be done for reasons other than test, as for example circuit performance, or due to error in the implementation. Even if the branches are different (number of flops, inversions, etc.), there will be a fixed, known relationship between the data in both branches, and that relationship can be modeled using the teachings hereof. In this respect, the uses hereof may be broader than parallel scan implementation.

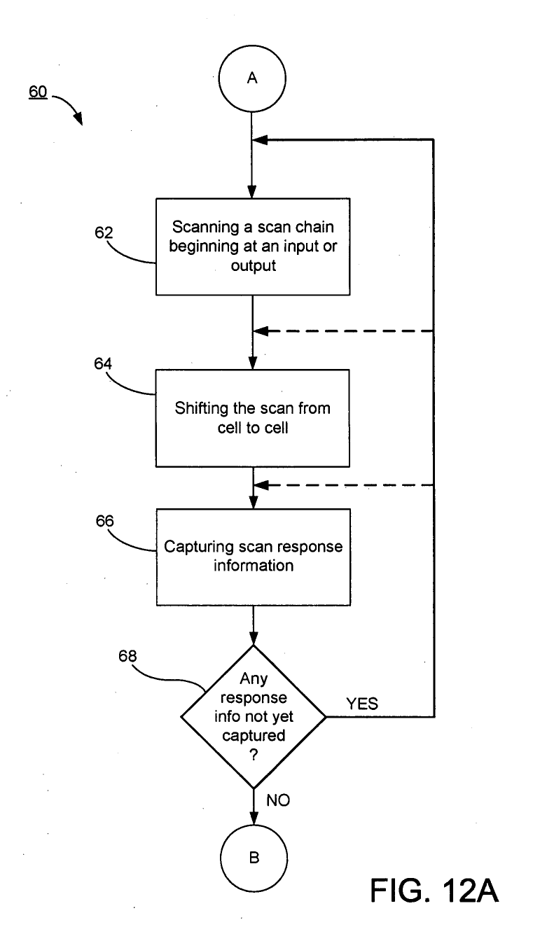

In creating the dummy cell branched version of the scan chain as found in chain 2000 of FIGS. 5 and 7, a process 50 as shown in FIG. 11 (either FIG. 11A or 11B, or the like) may be used. Note, the process 50 may be a part of and thus linked to another overall process for setting up and/or running a test program for a particular device (e.g., device(s) 10, 100, inter alia), or the process 50 may be separately disposed. In either case, i.e., setting up and/or running a test, the use of the phrase a test process includes either or both. Even so, it should be noted that a prominent utility may be in test pattern generation (e.g. ATPG, as described above), an example of a test set-up process. In which case, test pattern generation is many times, i.e. in most cases, performed as a separate, standalone process from the actual test application, although it could be connected in some embodiments to the test equipment and test process(es). In many examples, the test pattern is generated once and used a great many times in actual test application. In such cases, the test pattern generation can be run using a model of the IC (as is test pattern validation), whereas test application is re-done on each and every actual, physical IC. In any case, the presently described models and methods for generation and use thereof may be used for pattern generation, validation, application and/or any other process that uses or may use a model of the IC.

As a first part of this process (or sub-process) 50 as shown in both FIGS. 11A and 11B, and presuming a branched chain is provided (or a preliminary step of identifying branched chains to be fed into this process 50), the parent and the stub portions, e.g., portions 20 and 30 respectively (see FIG. 4), of the given branched chain, e.g., chain 200, are identified, see step 52 in FIG. 11 (both FIGS. 11A and 11B). A second step 54 may then involve the creation of the dummy cell chain and connection thereof to the stub or branch portion 30 and/or to the SIN, as in SIN 21 (again, see both FIGS. 11A and 11B). Another way of viewing this second step 54 is that the stub may be disconnected from the parent segment and dummy cells or flops are stitched from the disconnected point to the SIN of this chain. A next step in one embodiment (FIG. 11A) may be considered the completion of this process, see step 56; which may include completion of the test setup process, also step 56; and/or which could involve return to another process for setting up a test, or could merely represent the final step in the test setup process, whether overall or for this process 50 as a separate entity. If this step 56 could merely represent the end of this sub-process 50, it may not actually represent a step to be taken. However, an alternative step may be established in this process for looping back to take care of one or multiple branch situations, see e.g., FIG. 11B. In this alternative process 50 includes a decision determination step 58 for determining whether there are any remaining branches which need to be connected with a dummy chain. If there are one or more remaining branches then, the step 58 returns operation to dummy cell creation/connection step 54 (solid line) or back to the identification step 52 (dashed line). Otherwise, if there are no further branches, then the process/sub-process 50 ends.

In either case, the process may be related to the creation of flops/cells for actual use on an IC device, like device 100 (FIG. 3) e.g., or may be used in the creation of a model, also known as an electronic representation of the IC device 100, the model providing the ultimate actual interface with the ATPG and/or test equipment (ATE). In this latter situation, the ATPG and/or ATE software may operate on a model hereof to generate vectors, or in the case of the ATE software, as if it were feeding test vectors through the SIN 21 to multiple (two or more) parallel scan chains simultaneously, and as such, the ATE software may then keep accurate track of the values on each of the cells/flops, regardless whether they represent real cells/flops, e.g., cells/flops 11-16, and 31, 32 or dummy flops, e.g., flops 111, 112, 113. The resulting output is then assured. In one summary embodiment, for each branch, the method, or a tool employing the method creates a number of dummy scan cells equal to the scan cells in the parent up to the point of the branch, and then connects these dummy cells into a dummy scan chain which has its input connected to the parent scan input, and the output connected to the branch scan input.

Note, a tool according to the teachings hereof may be considered as that which creates a model or electronic representation; or a tool may alternatively and/or additionally be considered the model or electronic representation itself, particularly as it may be used in test pattern generation, validation or the actual testing of the device. For example, such a use in a test process (test pattern generation, validation or actual testing) for an electronic circuit device may include use of the model or electronic representation, the model or electronic representation including any of a branched scan chain of the circuit device, the branched scan chain having scan cells in a parent portion and a branched portion, the branched portion branching off of the parent portion; the model also including a representative parent portion of scan cells, and a branched dummy portion of scan cells. As above, the representative parent portion may be an electronic representative of the scan cells of the parent portion of the branched scan chain of the electronic device, and the branched dummy portion would include a model of the scan cells of the branched portion of the branched scan chain of the electronic circuit device; and one or more dummy scan cells disposed prior to the model of scan cells. The representative parent portion is disposed to communicate with the branched chain and the scan cells thereof, including the dummy cells. Then, such a tool may provide an electronic intervention between the circuit device and the test equipment software and/or an automated test pattern generator.

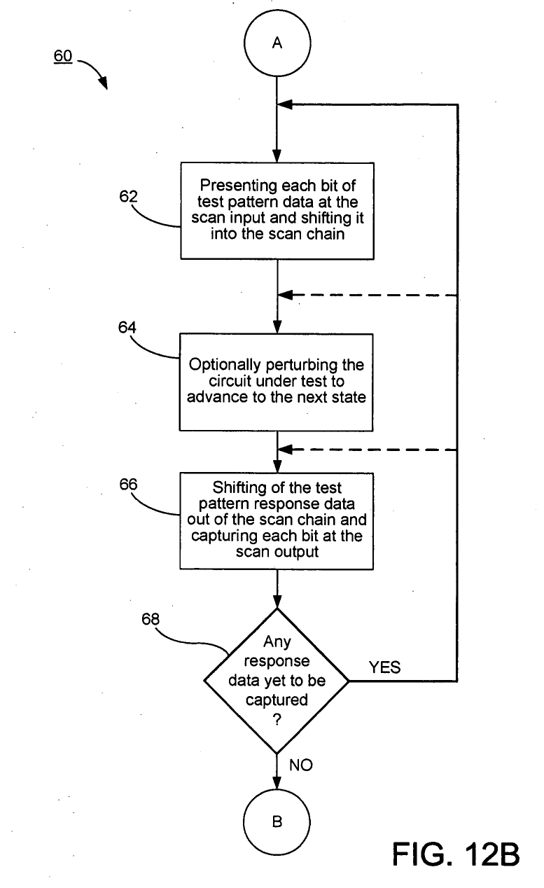

FIG. 12, including sub-part FIGS. 12A and 12B, illustrates methods or at least a part of a method 60 for using the models hereof with any scan methodology and/or with any scan tool using a scan chain model. This may include either setting-up a test and/or testing an IC device such as IC devices 10, 100 and/or 101. A first such method as in FIG. 12A, generally includes: scanning 62 a scan chain, beginning at either a scan chain input or output; shifting 64 the scan from cell to cell along the chain; and capturing 66 scan information from the scan with a return 68 possible, if there is more scanning to be initiated as at 62 or scan shifting as at 64 or information capturing as at 66. If this is used in ATPG, the steps may be interpreted as trace scanning beginning either at the output or at an input and shifting from cell to cell, and then capturing the information for use in creation of a model, and/or actually including a step of creating the model, or in creating of the test pattern itself. If used in actual testing, the steps are inputting 62 test data into a first scan cell 11 (FIGS. 1 and/or 3) as at SIN 21, shifting 64 test data from the first scan cell 11 to a second cell 12 (or between any other communicating cells), and, capturing 66 response data from the test, as at SOUT 22 (and/or SOUT 33 and/or any other like output). As the scan test is usually a serially inputted test vector, inputted one bit at a time based upon the pulsed of the shift master (SFTMA), then each of the steps 62, 64, 66 will also usually proceed in the pulsed shift fashion, the shifting occurring while the inputting is occurring, except in the first instance, and the capturing of data at the SOUT occurring also one bit at a time, but not until the first bits have traversed the entire scan chain 20, 200, 2000 and/or 2001. Thus, the loop from decision diamond 68 returns to the inputting step 62 (solid line) until there remain no longer any data bits to be input, but remain bits to be shifted cell to cell wherein the return loop returns operation to the shifting step 64 (dashed line) until there remain no more data response bits to be captured, step 66. Or, as in FIG. 12A, in the first box or step 62 is the step of presenting each bit of test pattern data at the scan input and shifting it into the scan chain. Then, in step 64 is optionally perturbing the circuit under test to advance to the next state, as for example by firing a clock, making a measurement, etc. And, then, in step 66 is the shifting of the test pattern response data out of the scan chain and capturing each bit at the scan output. Note that in practice, step 66 from the previous scan pattern is interleaved with step 62 from the current pattern. This effectively cuts the scan shifting in half. Thus, a scan test of three patterns could look like this:
Scan in pattern 1
Do something to the chip
Scan out pattern 1
Scan in pattern 2
Do something to the chip
Scan out pattern 2
Scan in pattern 3
Do something to the chip
Scan out pattern 3
   but may more efficiently expressed like this:
Scan in pattern 1
Do something to the chip
Scan out pattern 1 while scanning in pattern 2
Do something to the chip
Scan out pattern 2 while scanning in pattern 3
Do something to the chip
Scan out pattern 3.

Again, if used in an actual test, the test is launched into the first scan cell 11 and/or dummy cell 111 by outputting the test data from a signal generator in, of or associated with the test equipment. In the situation where dummy cells are added to the IC device 100, then the test vector is launched into and passed through such a dummy cell 111; however, in a situation where a modeled dummy chain is used, the IC device 100 may remain stubbed or branched, but the model interface between the test equipment signal generator and the IC device 100 presents a dummy chain 2000 to interface with the signal generator, and provides for communicating the appropriate signals then to the IC device 100. The signal generator then provides conditioned test data to the IC 100.

In conformance with the constraints under which it operates, the signal generator may provide test data to the IC in a number of forms. In one form, some or all of the test data may comprise a series of pulses. For example, in one embodiment, the signal generator may receive instructions of logic high test data which may then cause the signal generator to provide a series of pulses to the IC, and/or the signal generator may receive instructions of logic low test data which may then cause the signal generator to provide a logic low to the IC. In another embodiment, the signal generator may receive instructions of logic high test data which may then cause the signal generator to provide the IC with a series of pulses having a first set of characteristics (e.g., a first frequency, duration, and/or duty cycle), and/or the signal generator may receive instructions of logic low test data which may then cause the signal generator to provide the IC with series of pulses having a second set of characteristics (e.g., a second frequency, duration, and/or duty cycle).

The test equipment or systems with and/or in which the tools and/or methods hereof may be used may include automated test equipment (ATE) and/or other electronic device test equipment such as is available from various suppliers including Agilent Technologies, Inc., Palo Alto, Calif., USA. Also, the tools and/or methods hereof may be software or computer programs and/or resident in one or more computer programs or parts thereof, and thus may be code or program code and/or may be resident in or on computer readable media. The tool and/or method may thus provide for creation of a model or an electronic representation or other simulation of the scan chain of the circuit device (IC or circuit board), the model being resident in/on a computer, in/on a part of software or a computer program and/or in/on computer readable media. The model may be displayable or merely interactive with the test equipment, as for example with the computer associated with the test equipment in a form representing the circuit device to be tested such that the computer associated with the test equipment reads the model of the circuit device as though the circuit device actually has the dummy cells 111, 112, 113 or the like, even if the actual circuit device does not indeed have such cells.

In some embodiments, the model and/or the tool and/or method for the creation thereof may be a part of the computer program of the test equipment itself, or it may be separate software which communicates or is adapted to communicate with the computer of the test equipment. It may also be a part of or otherwise adapted to communicate with an automated test pattern generator (ATPG) which may be a part of or otherwise communicate with the test equipment. In an alternative, the tool and/or method may include hardware or firmware in addition to or in lieu of the software/program component. In one such example, actual physical dummy cells or flops may be used, either incorporated directly on to the electronic device or otherwise communicative to and with the scan chain thereof. Otherwise, physical hardware may be used between the electronic device to be tested and the test equipment, the intervening physical hardware then simulating the dummy cell chain as described herein.

It should be noted that the FIG. 9 method may be performed as part of IEEE Standard 1149.1 INTEST- and/or EXTEST-based testing, thus leveraging standardized testing methodologies.

While illustrative and presently preferred embodiments of the invention have been described in detail herein, it is to be understood that the inventive concepts may be otherwise variously embodied and employed, and that the appended claims are intended to be construed to include such variations, except as limited by the prior art.

1. A tool for use in a process related to testing a circuit device, comprising:
code for identifying a respective parent portion and any respective branch portions of a scan chain of a circuit device, the scan chain having a scan input and one or more scan outputs and a plurality of scan cells disposed therebetween; and
code for creating a model of the scan chain, including
code for creating a dummy cell chain which includes creating one or more dummy cells and connecting the one or more dummy cells between the scan input and a branch portion of the scan chain.

2. A tool as in claim 1, wherein the process related to testing a circuit device is a process selected from the group consisting of: creating a test, generating a test pattern, automatically generating a test pattern, validating a test, verifying a test, setting up a test or running a test.

3. A tool according to claim 1 wherein the code for creating a dummy cell chain further includes code selected from the group consisting of:
code for breaking the branch portion from the parent portion of the scan chain in the model;
code for inserting the one or more dummy cells in the branch chain immediately prior to the existing cells in the branch chain and immediately after the scan input;
code for creating the dummy chain in parallel to the parent chain; and
code for creating exactly the same number of dummy cells exactly matching the number of non-branched parent cells in the parent portion of the scan chain.

4. A tool as in claim 1, further including code for preliminarily determining whether the scan chain has a plurality of outputs.

5. A tool as in claim 1, further including code selected from the group of code for determining whether there remain any branch portions of the scan chain for which a dummy cell chain may be created; and code for determining whether there remain any branch portions off another branch portion of the scan chain for which a dummy cell chain may be created.

6. A tool as in claim 1, wherein the tool is at least part of a computer program and the code portions thereof are program codes.

7. A tool as in claim 1, wherein the tool is at least partly comprised of hardware.

8. A tool as in claim 1, wherein the circuit device is selected from the group consisting of an IC device and a circuit board.

9. A tool as in claim 1, wherein the model is communicated to circuit test equipment for use during testing of the circuit device.

10. A tool as in claim 1, wherein the tool is adapted to communicate with apparatus selected from the group consisting of: test equipment; or automated test equipment; or computer equipment for test pattern generation or validation.

11. A tool as in claim 1, wherein the tool forms a part of apparatus selected from the group consisting of: test equipment; or automated test equipment; or computer equipment for test pattern generation or validation.

12. A tool as in claim 1, wherein the tool provides an abstract software model of the circuit device to apparatus selected from the group consisting of: test equipment, automated test equipment and computer equipment for test pattern generation or validation.

13. A tool for use in a test process for a device, comprising:
means for identifying respective parent and branch portions of a scan chain of the device; and
means for creating an model of the scan chain, including
means for breaking the branch portion from the parent portion of the scan chain in the model;
means for inserting one or more dummy cells in the branch chain prior to the existing cells in the branch chain; and
means for re-connecting the branch chain with the inserted dummy cells to the scan input in the model of the scan chain.

14. A tool for use in a test process for a circuit device comprising:
an electronic representation of a branched scan chain of the circuit device, the branched scan chain having scan cells in a parent portion and a branched portion, the branched portion branching off the parent portion;
whereby the electronic representation includes:
a representative parent portion of scan cells, and
a branched dummy portion of scan cells,
whereby the representative parent portion is an electronic representative of the scan cells of the parent portion of the branched scan chain of the circuit device, and
whereby the branched dummy portion includes:
an electronic representative of the scan cells of the branched portion of the branched scan chain of the circuit device; and
one or more dummy scan cells disposed prior to the electronic representative scan cells of the branched portion of the branched scan chain, and whereby the dummy scan cells are connected to the electronic representative of the scan cells of the branched portion of the branched scan chain, such that the dummy scan cells are disposed to communicate therewith.

15. A tool as in claim 14, wherein the tool is an abstract software model of the circuit device used with apparatus selected from the group consisting: of test equipment; automated test equipment; and computer equipment for test pattern generation or validation.

16. A system for setting up a test for a circuit device comprising:
a test pattern generator which receives input relative to a circuit device to be tested and which outputs a test pattern for testing the circuit device;
a tool which operates with the test pattern generator, the tool having
means for identifying respective parent and branch portions of a scan chain of a circuit device, the scan chain having a scan input and a plurality of scan outputs and a plurality of scan cells; and
means for creating an model of the scan chain, including
means for creating a dummy cell chain which includes the branch portion of the scan chain connected with one or more dummy cells and the scan input.

17. A method for modeling test circuitry of a device comprising:
identifying respective parent and branch portions of a scan chain of the device, the scan chain having a plurality of scan cells and at least one scan input and a plurality of scan outputs; and
creating a model of the scan chain, the model comprising the parent portion of the scan chain, and dummy cells connected between the scan input and the branch portion of the scan chain.

18. A method as in claim 17, wherein said creating a model further comprises:
disconnecting the branch from the parent.

19. A method for performing a test-related process for a circuit device comprising:
identifying respective parent and branch portions of an actual scan chain of a circuit device, the actual scan chain having a plurality of scan cells and at least one scan input and a plurality of scan outputs; and
creating a model of the scan chain, including
creating a dummy cell chain which includes the branch portion of the scan chain connected with one or more dummy cells and the scan input.

20. A method as in claim 19, wherein the test-related process is a process selected from the group consisting of: creating a test, generating a test pattern, automatically generating a test pattern, validating a test, verifying a test, setting up a test or running a test.

21. A method for testing a circuit device comprising:
using an model of a scan chain of a circuit device, including a parent portion and a dummy cell portion of the representative chain, the dummy cell portion including the branch portion of the scan chain connected with one or more dummy cells and a common scan input which is in common with the parent portion;
shifting test bits into a common scan input;
populating the parent and the dummy portions of the model which includes populating the branch portion of the scan chain; and
capturing a response to the test bits shifted into the scan input.
